(19) United States
(12) Patent Application Publication
(10) Pub. No.: US 2016/0003896 A1
(43) Pub. Date: Jan. 7, 2016

(54) WIRELESS REMOTE POWER EQUIPMENT TEST SYSTEM AND METHOD OF USING SAME

(71) Applicant: TRINITY SOLUTIONS LLC, Mount Nebo, WV (US)

(72) Inventors: Christopher S. Skaggs, Victor, WV (US); Michael C. Pritt, Victor, WV (US); William J. Warren, Ansted, WV (US); William C. Cook, II, Oceana, WV (US)

(21) Appl. No.: 14/735,355

(22) Filed: Jun. 10, 2015

Related U.S. Application Data
(60) Provisional application No. 62/011,233, filed on Jun. 12, 2014.

(51) Int. Cl. G01R 31/28; G01R 31/02; G01R 31/42

(52) U.S. Cl. CPC G01R 31/2884; G01R 31/42; G01R 31/025

(57) ABSTRACT

Methods, systems, and devices are disclosed for the wireless remote testing of power equipment and for recording and reporting the associated test results.

The present application is a non-provisional application and claims priority under 35 U.S.C. 119 to provisional application No. 62/011,233 filed on Jun. 12, 2014, the entirety of which is hereby incorporated by reference.

### TECHNICAL FIELD

The present application generally relates to devices, systems, and methods for improving the safety of testing power equipment and improving the accuracy in recording the results of such testing. More specifically, the present application relates to devices, systems, and methods for remotely testing power equipment and recording the results thereof using wireless technology.

### BACKGROUND

Working on energized power equipment is inherently dangerous. For example, short circuits occurring when conductors of opposite polarity are bridged by a conductive object such as a metal screwdriver, wrench, or test equipment, may cause portions of the conductors or other metallic materials to explode violently causing a flash that may result in permanent eye damage while expelling shrapnel and showering molten metal that may cause serious injuries or even death. Moreover, as the human body will conduct electrical current, inadvertent contact with the live equipment can cause a circuit path through both arms, through an arm or leg to ground, or through any body surface to ground, which can result in severe burns and death by electrocution.

Traditional methods of ensuring the proper functioning of power equipment required qualified personnel to perform tests within close proximity of the power equipment thereby exposing the individual to the dangers outlined above. The frequency with which certain power equipment must be tested increase the odds that injury will occur. For example, low and medium voltage three phase AC circuits in underground mines must be tested in accordance with 30 CFR §75.900-3 of the Code of Federal Regulations which states:

Testing, Examination, and Maintenance of Circuit Breakers; Procedures.
Circuit breakers protecting low- and medium-voltage alternating current circuits serving three-phase alternating current equipment and their auxiliary devices shall be tested and examined at least once each month by a person qualified as provided in §75.153. In performing such tests, actuating any of the circuit breaker auxiliaries or control circuits in any manner which causes the circuit breaker to open, shall be considered a proper test. All components of the circuit breaker and its auxiliary devices shall be visually examined and such repairs or adjustments as are indicated by such tests and examinations shall be carried out immediately.

Furthermore, all such tests must be recorded in accordance with 30 CFR §75.900-4 which states:

Testing, Examination, and Maintenance of Circuit Breakers; Record.
The operator of any coal mine shall maintain a written record of each test, examination, repair, or adjustment of all circuit breakers protecting low- and medium-voltage circuits serving three-phase alternating current equipment used in the mine. Such record shall be kept in a book approved by the Secretary.

As mentioned above, traditionally these tests have been conducted using hand held devices with the results recorded in handwritten form by the qualified individual performing the test. Examples of such prior art hand held test apparatus include the Service Machine Corporation SMC-3100 “Safety Circuit Tester” as well as hand-held multi-meters, amp meters, and even the insertion of a fused wire between a phase conductor and ground to facilitate a ground fault condition. While such devices can be used to perform the required test procedures needed to satisfy, for example, 30 CFR 75.900-3, due to the qualified person having to physically touch the power equipment to perform the tests and therefore to perform the tests in close proximity to potentially hazardous voltages, the individual is exposed to the serious risk of electrical shock and/or arc flash hazard as described above. Moreover, recording the method through handwritten documentation to comply with 30 CFR 75.900-4 is subject to human error. According, a need exists for a test unit that will allow qualified persons to perform testing on power equipment, such as that required by 30 CFR 75.900, without placing themselves unnecessarily in harm's way. Further, a need exists for a means to record and to store associated test results in a way that eliminates the human element to prevent any accidental error in the recording of such tests.

### SUMMARY

According to one aspect of the disclosure, embodiments of a wireless automated circuit test unit, system and method are provided, including embodiments that will satisfy 30 CFR 75.900-3.

According to an aspect of the disclosure, embodiments of a wireless power equipment test unit, system, and method are provided, including embodiments having a test unit physically connected to the circuit under test and wirelessly connected to a tablet or similar device for operator interface from a safe distance from the circuit under test.

According to an aspect of the disclosed subject matter, embodiments of a wireless test unit, system, and method that will record and save test data to storage media are provided.

According to another aspect of the disclosed subject matter, embodiments of a wireless test unit, system, and method that will generate and store a report of the test results are provided, including embodiments that may satisfy 30 CFR75.900-4.

According to yet another aspect of the disclosed subject matter, embodiments of a wireless test unit, system, and method that will generate a report of the test results remotely, including embodiments that may satisfy 30 CFR75.900-4.

### BRIEF DESCRIPTION OF THE DRAWINGS

The disclosed subject matter of the present application will now be described in more detail with reference to exemplary embodiments of the apparatus, system, and method, given by way of example, and with reference to the accompanying drawings, in which:

FIG. 1 is a block diagram of a wireless automated circuit test system in accordance with one embodiment of the disclosed subject matter.

FIG. 2 (also provided as FIG. 2a, FIG. 2b) is a flowchart for one embodiment of the disclosed subject matter demonstrating a process that may be utilized to test power equipment.

FIG. 3 is a high level block diagram depicting the test unit connected wirelessly to a tablet/PC and wired to a power center circuit panel in accordance with an embodiment of the disclosed subject matter.

FIG. 4 is a block diagram depicting exemplary components of a power center circuit panel to be tested and the connection of an automated circuit tester in accordance with one embodiment of the disclosed subject matter.

FIG. 5 illustrates an exemplary underground mining power distribution system.

FIG. 6 illustrates an exemplary electrical schematic of a power center.

FIG. 7 illustrates a possible component place for one embodiment of a power center.

FIG. 8 illustrates an exemplary report that may be generated and the data that may be saved in accordance with an embodiment of the disclosed subject matter.

### DETAILED DESCRIPTION OF EXEMPLARY EMBODIMENTS

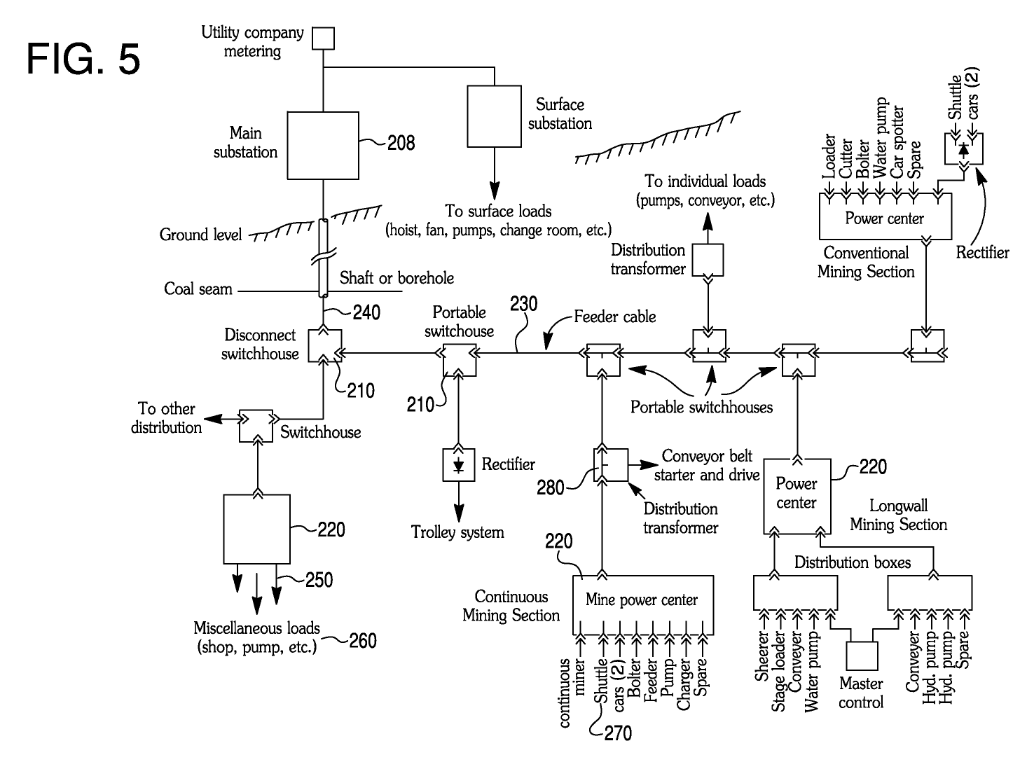

Power distribution systems distribute electrical energy from a power grid or other energy source for use, depending on the application, by residential, commercial, and industrial power systems. One such application is illustrated in FIG. 5, showing an exemplary power distribution system 200 for an underground mine. Such mine power distribution systems, and their specific components, are regulated by rule 30 CFR 75 of the Code of Federal Regulations. A general description of common mine power distribution systems are given in “Mine Power Systems” Information Circular 9258, herein incorporated by reference. As shown in FIG. 5, components of a mine power distribution system may include, among other things, a substation 208, a switchhouse 210, a power center 220, cabling 230, 240, 250, fixed mining equipment 260 and mobile mining equipment 270, and distribution transformer 280.

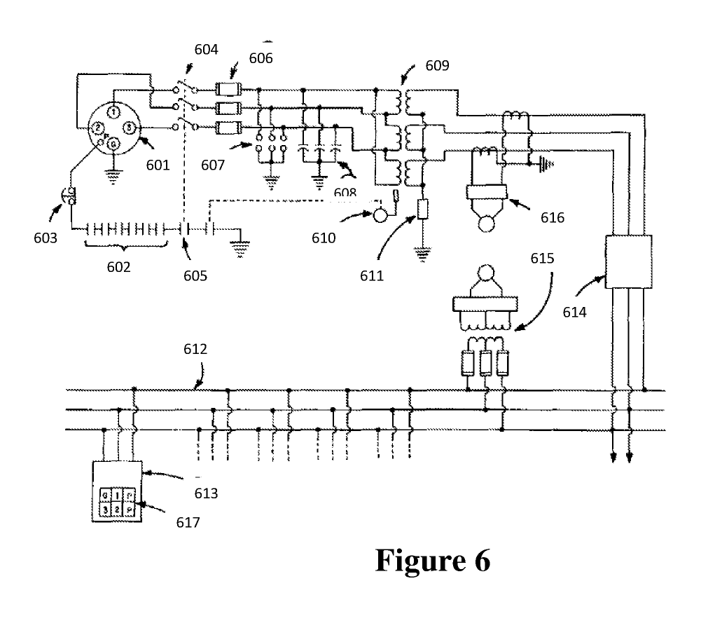

Power centers 220 and distribution transformers 280 may function as portable substations, transferring and converting the distribution voltage to utilization levels. Each power centers 220 and distribution transformers 280 has its own set of internal protection components such as emergency stop switches and interlock switches. As shown in FIG. 6, common electrical components of a typical mine power center 600 may include high-voltage coupler 601, interlock switches 602, emergency-stop switch 603, disconnect switch 604, pilot-break monitor 605, high-voltage fuses 606, surge arresters 607, surge capacitors 608, power transformer 609, temperature device 610, grounding resistor 611, busway 612, outgoing circuit breaker 613, main circuit breaker 614, voltage metering 615, current metering 616, and outgoing cable coupler 617.

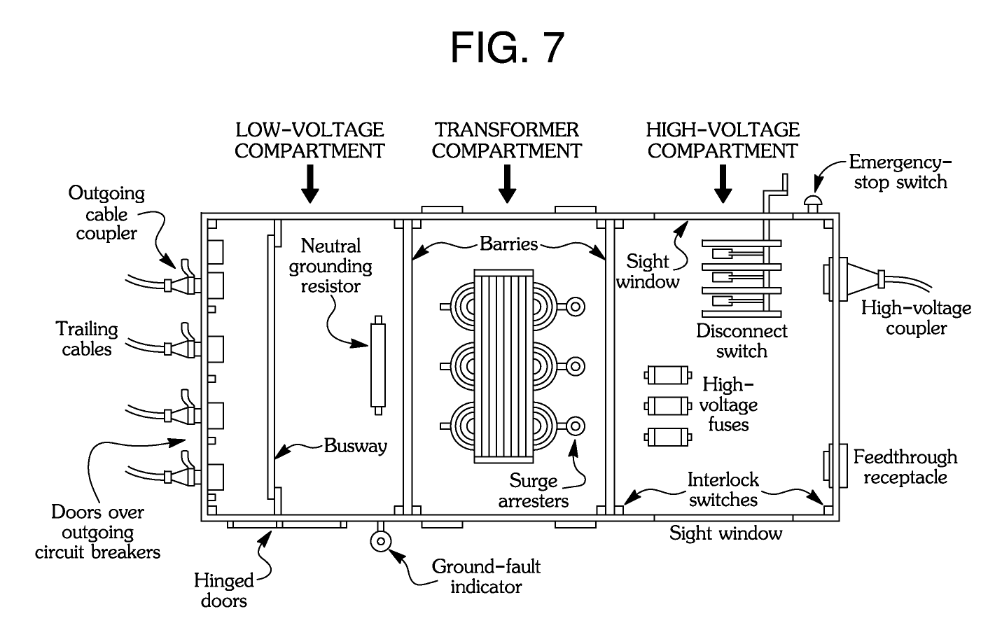

FIG. 7 illustrates a possible component placement for one embodiment of a power center in which the power center is sectionalized into separate compartments—high voltage, transformer, and low-voltage or medium voltage—for added safety. Other component placement will be known to the ordinary artisan.

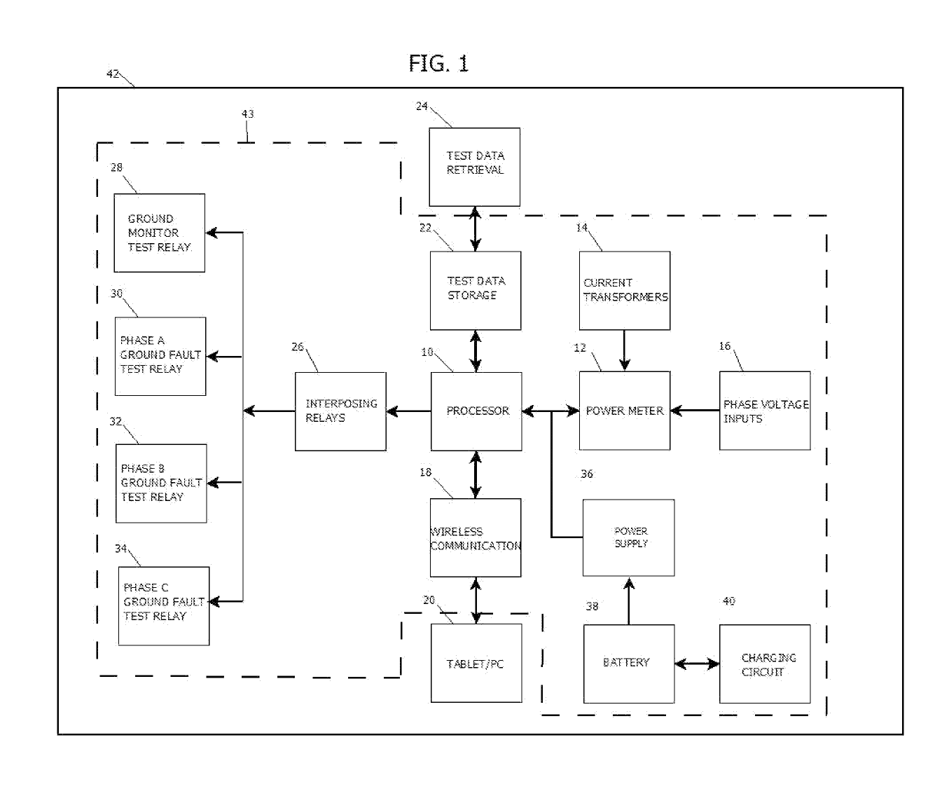

FIG. 1 illustrates a wireless automated circuit test system 42 in accordance with one embodiment of the subject disclosure. Wireless automated circuit test system 42 may satisfy, for example, the testing and reporting criteria of 30 CFR 75.900-3 and 30 CFR 75.900-4 in a mining application. Wireless automated circuit system 42 may include processor 10, power meter 12, current transformers 14, phase voltage inputs 16, wireless communication unit 18, tablet/PC 20, test data storage device 22, test data retrieval device 24, interposing relays 26, ground monitor test relay 28, phase A ground fault test relay 30, phase B ground fault test relay 32, phase C ground fault test relay 34, power supply 36, battery 38, and charging circuit 40.

In various embodiments, processor 10 can be a single Integrated Circuit with supporting electronic components, a module such as the Rabbit RCM-6760, or other implementation as will be known to the ordinary artisan. Further, processor 10 may participate in bidirectional communications with wireless communications unit 18, embodied for example by devices such as the Digi WiMX-28. In one or more embodiments, wireless communications unit 18 may communicate wirelessly and/or bi-directionally with tablet/PC 20, implemented for example by the Getac T800, thereby allowing tablet/PC 20 to transmit communication signals to, and to receive communication signals from, processor 10 through wireless communication unit 18.

Processor 10 may also communicate bi-directionally with power meter 12, embodied for example by the ADE7878 or like devices. Power meter 12 may receive inputs from current transformer 14 and phase voltage inputs 16 and may convey the information received via a digital serial signal such as I2C to processor 10. Processor 10 may transmit such test data to (and retrieve test data from) test data storage device 22. In one embodiment, test data storage device 22 is implemented using a MYDIGITALSSD MDMS-OTG-064. Other embodiments may use similar devices. Test data is retrieved from, and transmitted to, test data storage device 22 using test data retrieval unit 24, such as Microsoft Excel.

In one or more embodiments, processor 10 may send signals to interposing relays 26, such as the Clare CPC7514Z, to initiate and to control one or more of the switching of: ground monitor test relay 28 such as the Crydom CKRD6030, phase a ground fault test relay 30 such as the Crydom CKRD6030, phase b ground fault test relay 32 such as the Crydom CKRD6030, and phase c ground fault test relay 34 such as the Crydom CKRD6030.

Power supply 36 may provide the required power to processor 10, wireless communication unit 18, test data storage device 22, power meter 12, interposing relays 26, ground monitor test relay 28, phase a ground fault test relay 30, phase b ground fault test relay 32, and phase c ground fault test relay 34. In one embodiment, power supply 36 may be implemented using the Murata 78SR-5/2-C or like component. Further, power supply 36 may be powered by battery 38. In one embodiment, charging circuit 40 monitors the status of battery 38 and maintains the proper charge.

In one embodiment, the functionality of wireless remote test system 42 is distributed such that all the functionality except for the tablet/PC 20 is encompassed within an automated circuit tester 43 that wirelessly connects to tablet/PC 20. In other embodiments, the functionality may be distributed among one or more enclosures (or without enclosure) as dictated by need, application, or other parameters.

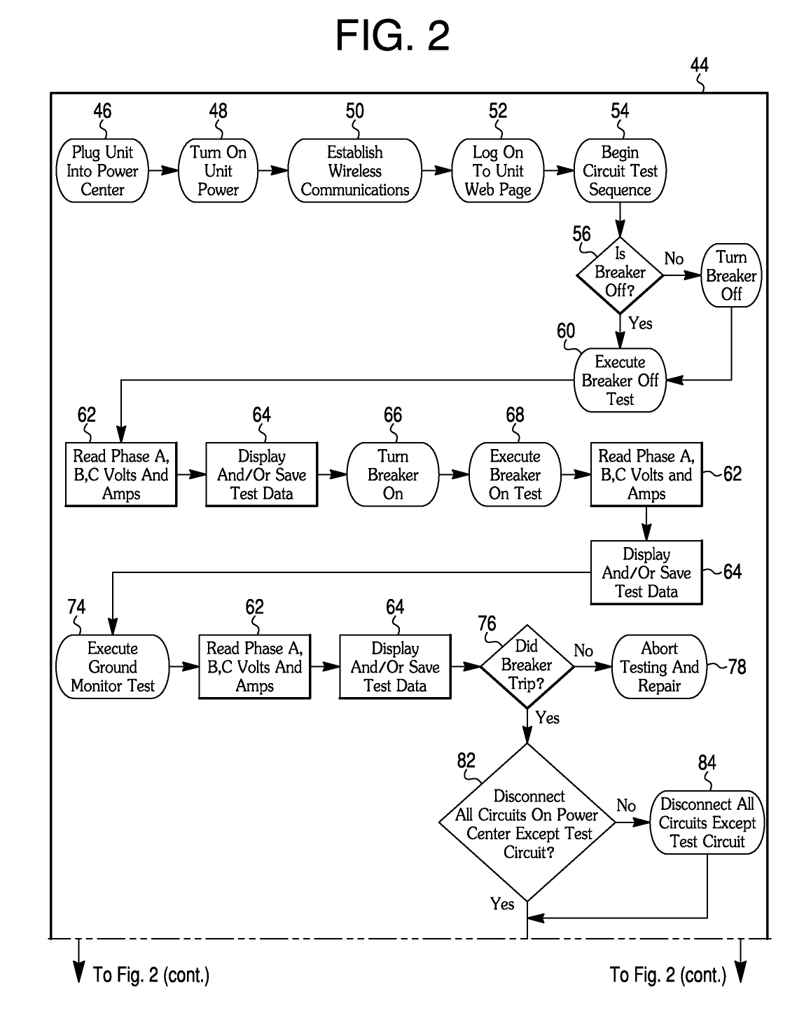

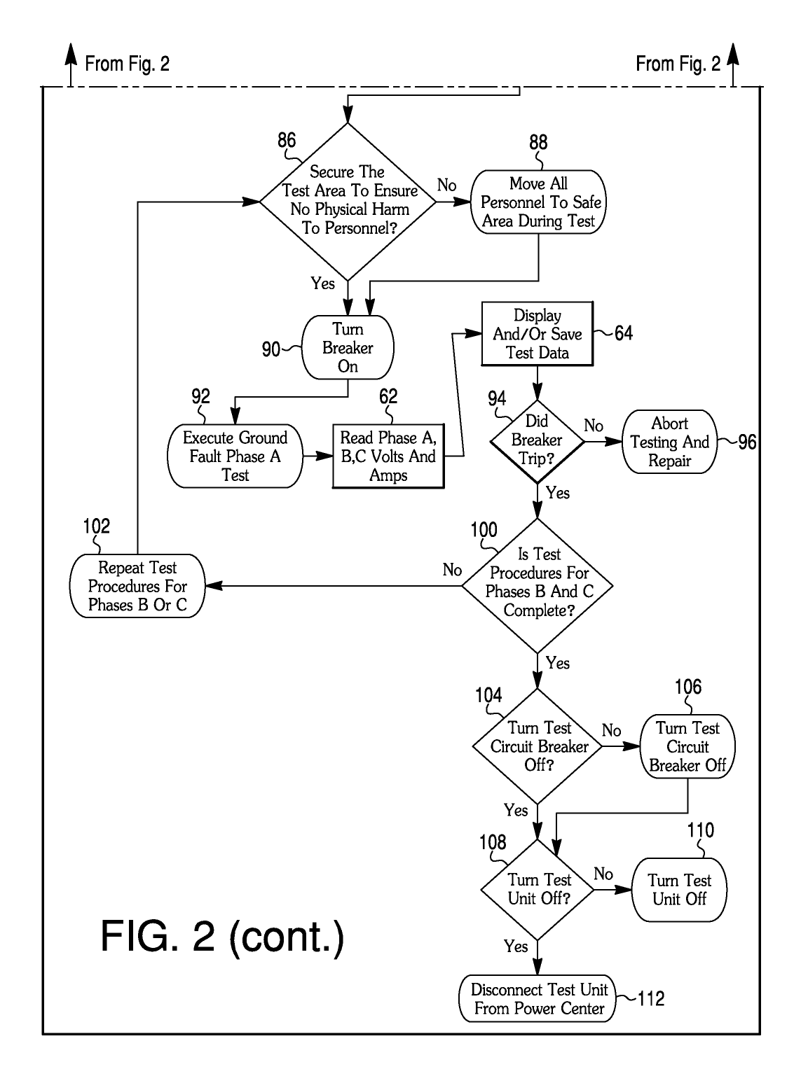

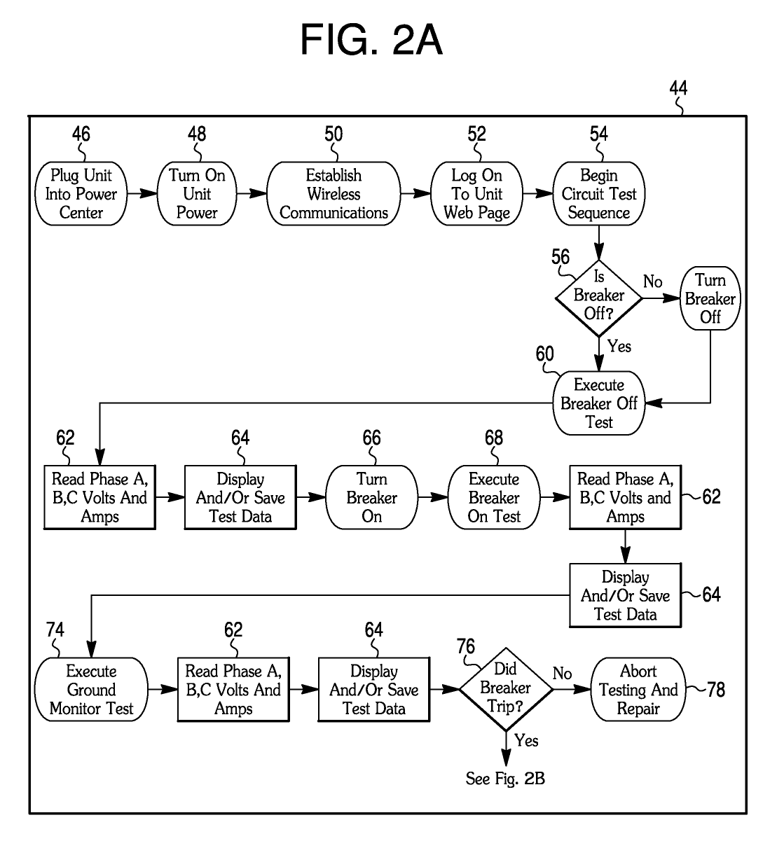

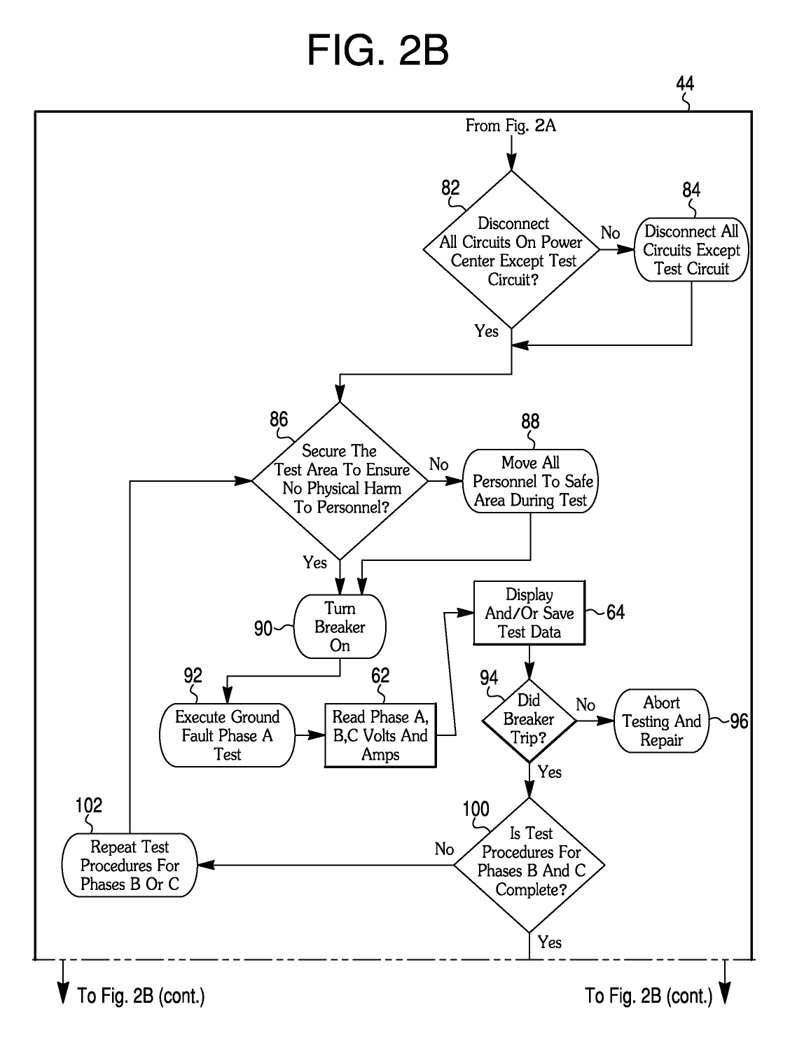

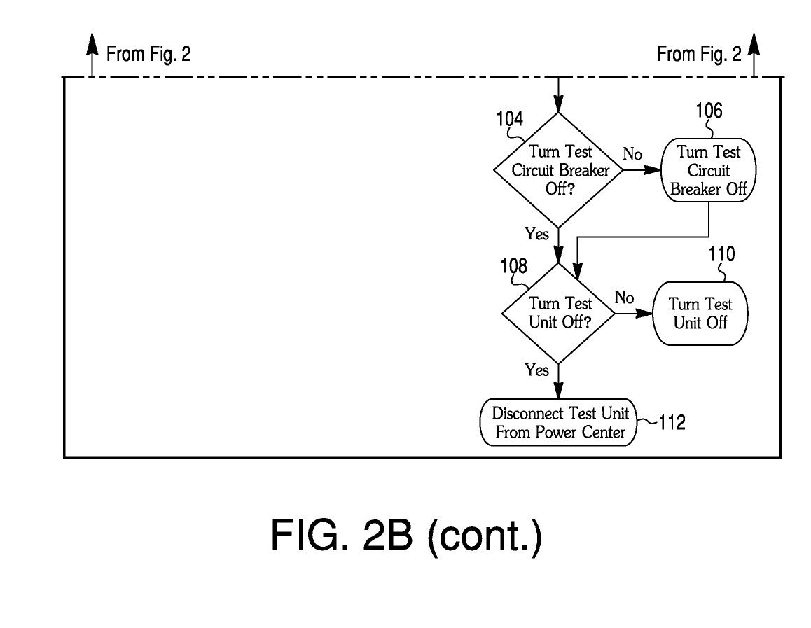

FIG. 2 (also provided as FIG. 2a, FIG. 2b) illustrates a flowchart for one embodiment of the disclosed subject matter demonstrating a process 44 that may be utilized to test power equipment. At step 46 (plug unit into power center), the automated circuit tester 43 is connected to a receptacle on the panel of the power center circuit 120 being tested. At step 48 (turn on unit power), automated circuit tester 43 is powered on by, for example, activating a power button or switch or booting the automated circuit tester 43 from the tablet/PC 20. At step 50 (establish wireless communications), if not already established, tablet/PC 20 (via program or operator control) initiates and establishes communication with wireless communication unit 18. At step 52 (log on to unit web page), tablet/PC 20 (via program or operator control) accesses a webpage on processor 10. At step 54 (begin circuit test sequence), processor 10 initiates the test sequence requested from the tablet/PC 20 (via program or operator control) using the accessed webpage. At step 56 (Is the breaker off?), the test process begins by assessing whether the breaker in the circuit being tested is in the off position as required for the test (via operator or system input). If the relevant breaker is not in the off position, at step 58 (Turn Breaker off), the breaker in the circuit being tested is placed in the off position (either manually or through program control). If the query returns the status that the breaker is off, or once the breaker is placed in the off position, at step 60 (Execute breaker off test), the breaker off test is initiated by processor 10 (via program or operator control). At step 62 (Read phase A, B, C Volts and Amps), processor 10 requests and receives the phase A, B, and C volts and amps readings from power meter 12. At step 64 (display and/or save test data), processor 10 sends the test data through wireless communication unit 18 to tablet/PC 20 for display and/or saves the test data to test data storage device 22. At step 66 (Turn Breaker On), processor 10 (via program or operator control) initiates a command to turn on the circuit breaker to which the test unit is connected. At step 68 (Execute breaker on test), processor 10 initiates the test of the relevant breaker while in the on position and repeats steps 62 and 64, requesting and receiving the phase A, B, and C volts and amps readings from power meter 12 and then displaying the test data on tablet/PC 20 via wireless communication unit 18 and/or saving the test data to test data storage device 22. At step 74 (Execute ground monitor test), processor 10 (via program or operator control) actuates interposing relays 26 to actuate ground monitor test relay 28 and repeats steps 62 and 64, requesting and receiving the phase A, B, and C volts and amps readings from power meter 12 and then displaying the test data on tablet/PC 20 via wireless communication unit 18 and/or saving the test data to test data storage device 22. At step 76 (Did breaker trip?), processor 10 determines if the circuit breaker tripped due to the increase in resistance in the Ground circuit caused by the actuating of Ground monitor relay 28. If the circuit breaker did not trip, at step 78 (Abort testing and repair), processor 10 aborts further testing and signals to the operator or other personnel that repair of the circuitry is warranted. If the circuit breaker did trip, then at step 82 (Disconnect all circuits on power center except test circuit?), processor 10 determines which circuits to disconnect based on operator or system input. For example, the operator may acknowledgement that the breaker did trip or the test system may determine that the breaker tripped based, for example, on the voltages on phases A, B, C (i.e., voltages are at or near 0 Volts). At step 84 (Disconnect all circuits except test circuit), processor 10 may initiate the disconnection of all circuits except test circuit. Alternatively, processor 10 may issue instructions to secure the test area to ensure no physical harm to personnel at step 86. At step 88 (Move all personnel to safe area during test), processor 10 issues instructions resulting in the movement of all personnel to safe areas during testing (e.g., audible or visual warning system may become active or alert to operator may be activated). If no personnel are in the test area, or once personnel are removed from the test area, then at step 90, processor 10 issues a command to turn breaker on (which may be performed manually or under program control) to begin ground fault testing. At step 92 (Execute ground fault phase A test), processor 10 initiates the ground fault test of phase A in the circuit being tested and repeats steps 62 and 64, requesting and receiving the phase A, B, and C volts and amps readings from power meter 12 and then displaying the test data on tablet/PC 20 via wireless communication unit 18 and/or saving the test data to test data storage device 22. At step 94 (Did the breaker trip?), processor 10 determines if the circuit breaker tripped to the off position due to a ground fault condition on phase A induced by the test unit through the closing of Phase A Ground Fault Test Relay 30. If the circuit breaker did not trip, then at step 96 (abort testing and repair), processor 10 aborts further testing and signals to the operator or other personnel that repair of the circuitry is warranted. If the circuit breaker did trip, then at step 100 (Is test procedures for phases B and C complete?), processor 10 determines whether similar testing to phase A testing has been completed for phases B and C. If phase testing for phase B and phase C has not been completed, then at step 102, beginning with step 86, the test procedures are repeated until phases A, B, C have all successfully been tested to open the circuit breaker under a ground fault condition. Once phases A, B, and C all have been tested successfully, at step 104 (turn test circuit breaker off?) processor 10 determines whether the most recently used test circuit breaker has been turned off. If the test circuit breaker has not been turned off, at step 106 (turn test circuit breaker off), processor 10 issues a command to turn off the circuit breaker that has just been tested. If the test circuit breaker has been turned off, at step 108 (turn test unit off), processor 10 queries whether automated circuit tester 43 has been turned off. If automated circuit tester 43 has not been turned off, it is powered down at step 110. If automated circuit tester 43 has been turned off, or once it is turned off, at step 122, the automated circuit tester 43 is disconnected from the power center, completing the testing for the power center equipment.

Other embodiments of process flows for the subject disclosure may, for example, alter the sequence of the various tests; incorporate operator control (via tablet/PC 20), programmed control, or combined control over processor 10.

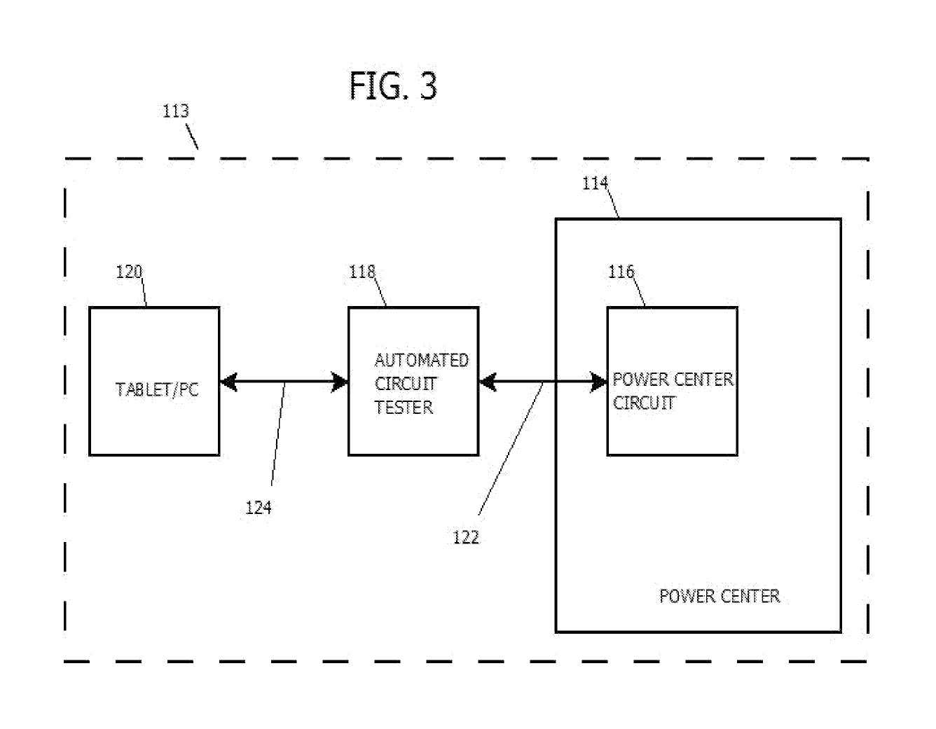

FIG. 3 illustrates a block diagram for one embodiment of a wireless remote power test system 113 of the subject disclosure incorporating tablet/PC 120 and automated circuit tester 118. In FIG. 3, power center 114 contains a plurality of power center circuits 116, such as those illustrated in FIG. 6 and/or FIG. 7, that may need to be tested frequently (e.g., weekly or monthly), in order to comply with requirements such as those set forth in accordance with 30 CFR 75.900-3 for mining applications. Automated circuit tester 118 may be connected to power center circuit 116 via a panel of the power center using connector 122 which could be a group of wires, a multi-conductor cable, one or more adapters, a combination thereof, or other comparable means. Tablet/PC 120 may be connected to the automated circuit tester 118 via a wireless link 124. Wireless link 24 could be WiFi, WiMax, ZigBee, blue tooth or other comparable technology. The wireless link 124 may have bidirectional communication ability to interact with, for example, tablet/PC 120 and also processor 10, with such receiving and transmitting capability implemented separately, as an integrated transceiver unit, or as a combination thereof.

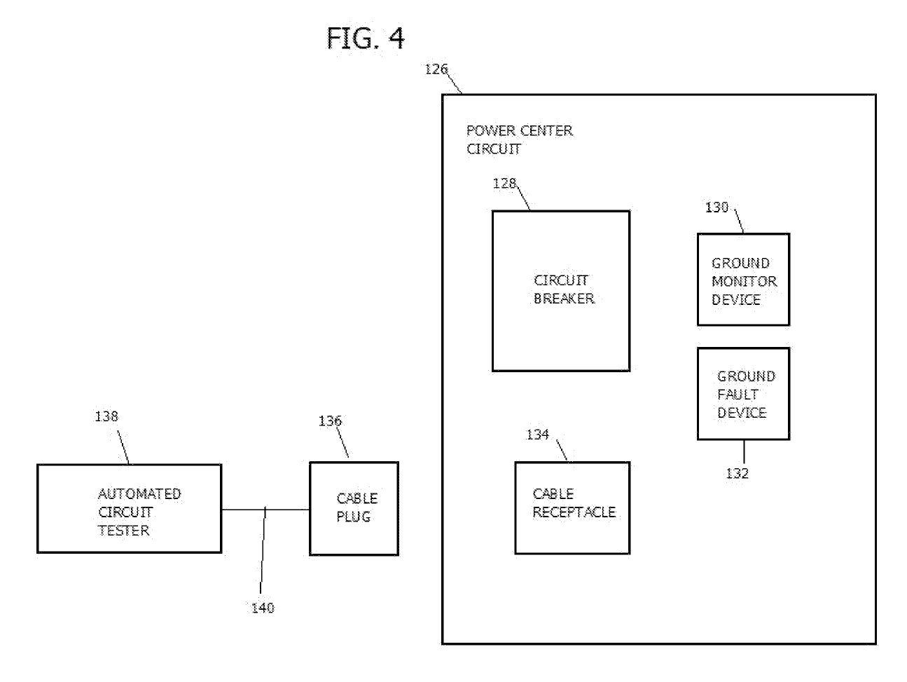

FIG. 4 illustrates a block diagram for an embodiment of the subject disclosure demonstrating connection and component breakdown of a power center circuit panel 126. For this embodiment, power center circuit panel 126 contains circuit breaker 128 that is designed to de-energize a machine cable (not shown) in the event of a short circuit, over current, ground fault, under voltage, or loss of ground circuit connection condition. Circuit breaker 128 supplies power to cable receptacle 134, which may be implemented using standard receptacles for a given application or may be specially made for a specific application. Ground monitor device 130 continuously checks the ground conductor circuit for continuity. The ground fault device 132 continuously checks the phases A, B, C for a ground fault condition. Cable Plug 136, which may contain adaptors for one or more standard cable receptacles 134 or be specially made for a particular application or both, connects automated circuit tester 138 to the power center circuit panel 126 through cable receptacle 134. Conductor 140, which may be one of individual wires, multi-conductor cabling, or comparable conductor, connects automated circuit tester 138 to cable plug 136. In one embodiment, automated circuit tester 138 performs the tests necessary to comply with 30 CFR 75.900-3 in mine applications.

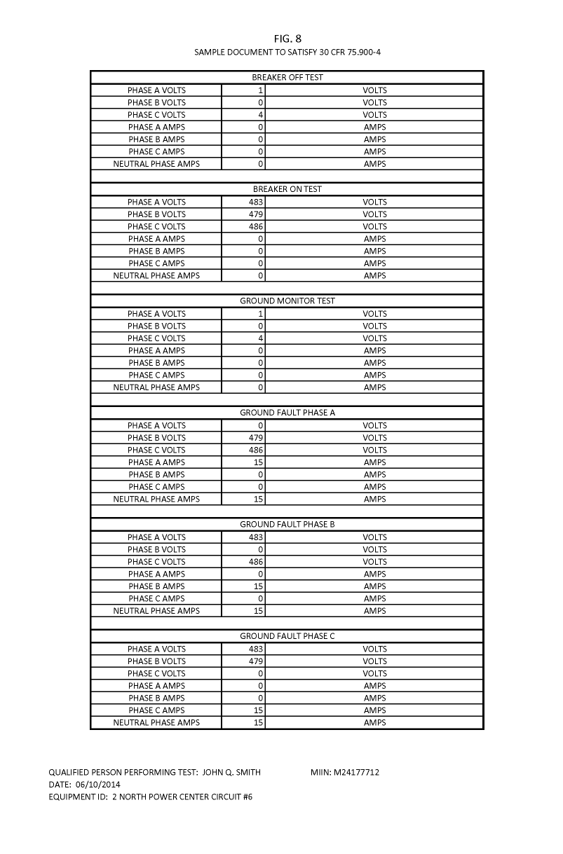

FIG. 8 illustrates an exemplary report that may be generated and the data that may be saved in accordance with an embodiment of the disclosed subject matter. As shown in FIG. 8, the report may include, among other information, all the data recorded during test conditions, the name of the qualified person performing the test, the qualified person's “MSHA Individual Identifications Number”, the date of the test, and the equipment being tested; and accordingly, the report may comply with, for example, the criteria of 30 CFR 75.900-4.

While certain embodiments of the subject disclosure are described above, it should be understood that material presented can be embodied and configured in many different ways without departing from the spirit and scope of the invention. For example, tablet/PC 20 could be a notebook, laptop, smart phone or other smart device as known to one of ordinary skill in the art. Moreover, test data storage device 22 and/or test data retrieval device 24 could be a remote PC or Server connected through some type of medium locally or remotely to store, retrieve, and compile reports as known to the ordinary artisan. Further, current transformers 14 could also be shunts, rogowski coils or current sensors, or current transducers while the phase voltage inputs 16 could be directly connected, utilize a resistor network, or utilize a potential transformer to read the voltage into the power meter. Furthermore, battery 38, power supply 36, and/or charging circuit 40 could be separate from or part of the automated circuit tester and could be one or many different parts. Also, with respect to the exemplary process disclosed, the associated steps may occur in many different orders and may be divided into additional steps or may combine steps, in order to perform any required testing process, such as that necessary to comply with 30 CFR 75.900-3. Further, while the functionality of, for example, the wireless remote test system and the automated circuit tester has been described using component language, the functionality of the components is not intended to be limited to a particular physical implementation. Functionality of one or more components may be combined into a single component or distributed to other components. Moreover, some of the functionality could be resident with the circuit under test. For example, in one embodiment, all functionality of automated circuit tester 43 except relays 28, 30, 32, and 34 may be placed within a power center in a mining application. Furthermore, the embodiments are not limited to testing low and medium voltage three phase AC circuits in underground mine power centers but may be adapted to test high voltage circuit performance of such power centers, other power equipment in the underground mines such as substations and switchhouses, or power equipment in other hazardous power systems, including residential, commercial, or other industrial applications.

While the subject matter has been described in detail with reference to exemplary embodiments thereof, it will be apparent to one skilled in the art that various changes can be made, and equivalents employed, without departing from the scope of the invention.

What is claimed is:

1. A power equipment test system for testing low and medium voltage three phase AC circuits comprising:
a computer for providing an operator interface for the power equipment test system; and
a test unit operable to perform the testing of the low and medium voltage three phase AC circuits; wherein the test unit is physically connected to the low and medium voltage three phase AC circuits and wirelessly connected to the computer such that the testing can be performed by an operator located remotely from the low and medium voltage three phase AC circuits.

2. The system of claim 1 wherein the low and medium voltage three phase AC circuits are resident within power equipment of an underground mine.

3. The system of claim 1 wherein the test unit comprises:
at least one processor connected to at least one power meter to receive test data during testing, the at least one power meter operably connected to the low and medium voltage three phase AC circuits to receive electrical input from the low and medium voltage three phase AC circuits;
at least one wireless communication device for wirelessly connecting the at least one processor to the computer;
at least one storage device connected to the at least one processor, the at least one storage device storing test data and reports generated by the processor from the test data; and,
at least one interposing relay connected to at least one ground fault test relay or at least one ground monitor test relay.

4. The system of claim 3 wherein the test unit further comprises at least one data retrieval device operably connected to the at least one storage device to at least one of retrieve test data stored in the at least one storage device, retrieve test reports stored in the at least one storage device, generate test reports from retrieved test data stored in the at least one storage device, print test reports stored in the at least one storage device, and print test reports generated from test data stored in the at least one storage device.

5. An automated low and medium voltage circuit test device comprising:
at least one processor connected to at least one power meter to receive test data during testing, the at least one power meter operably connected to the low and medium voltage circuits to receive electrical input from the low and medium voltage circuits;
at least one wireless communication device for wirelessly connecting the at least one processor to an external computer;
at least one storage device connected to the at least one processor, the at least one storage device storing test data and reports generated by the processor from the test data;
at least one interposing relay connected to at least one ground fault test relay or at least one ground monitor test relay and further connected to the at least one processor; and,
at least one data retrieval device operably connected to the at least one storage device to at least one of retrieve test data stored in the at least one storage device, retrieve test reports stored in the at least one storage device, and generate test reports from retrieved test data stored in the at least one storage device;
wherein the at least one processor controls the testing based on input received from the external computer.

6. The device of claim 5 wherein the electrical input comprises voltage and current inputs; the low and medium voltage circuits comprise low and medium voltage three phase AC circuits; and the power meter is physically connected to the low and medium voltage circuits.

7. The device of claim 5 wherein the test data is stored remotely from the device.

8. The device of claim 5 wherein a report is generated remotely from the device using the stored test data and saved in file format for later retrieval.

9. A method for testing power equipment using a computer remotely located from the power equipment and wirelessly connected to a test unit physically connected to the power equipment, the method comprising:
providing a computer as an operator interface to a test unit operable to perform the testing of power equipment; physically connecting the test unit to the power equipment; and wirelessly connecting the test unit to the computer; whereby the testing can be performed by an operator located remotely from the test unit and the power equipment.

10. The method of claim 9 wherein the power equipment is resident with an underground mine and comprises low and medium voltage three phase AC circuits.

11. The method of claim 10 wherein physically connecting the test unit to the low and medium voltage three phase AC circuits comprises operably connecting at least one power meter of the test unit to the low and medium voltage three phase AC circuits to receive electrical input from the low and medium voltage three phase AC circuits.

12. The method of claim 11 further comprising
connecting at least one processor to the at least one power meter to receive test data from the power meter at the at least one processor during testing;
testing the low and medium voltage three phase AC circuits;
receiving test data from the at least one power meter at the at least one processor during testing;
displaying the test data received at the at least one processor at the computer via the wireless connection between the computer and the test unit;
generating reports from the test data by the at least one processor; and,
storing the test data received at the at least one processor and the reports generated by the at least one processor in at least one storage device of the test unit.

13. The method of claim 12 wherein testing the low and medium voltage three phase AC circuits comprises actuating at least one interposing relay connected to at least one ground fault test relay or at least one ground monitor test relay.

14. The method of claim 12 further comprising:
retrieving test data stored in the at least one storage device;
retrieving test reports stored in the at least one storage device;
generating test reports from retrieved test data stored in the at least one storage device;
printing test reports stored in the at least one storage device; and
printing test reports generated from test data stored in the at least one storage device,
whereby the retrieving test data, retrieving test reports, generating test reports, printing test reports stored in the at least one storage device, and printing test reports generated from test data are accomplished via at least one data retrieval device operably connected to the at least one storage device.

15. The method of claim 14 further comprising storing test data and test reports in at least one storage device located remotely from the test unit and operably connected to the at least one data retrieval device.

16. The method of claim 9 wherein physically connecting the test unit to the power equipment comprises plugging an automated circuit tester into a receptacle on a panel of a power circuit to be tested; and wherein the testing of the power equipment comprises:
powering on the automated circuit tester by one of activating a power button, activating a power switch, and booting the automated circuit tester from a computer wirelessly connected to the automated circuit tester;
accessing a processor of the automated circuit tester from the computer wirelessly connected to the automated circuit tester;
initiating test sequences of a circuit breaker in the circuit being tested in both on and off position by the processor under one of program control and operator request from the computer;
receiving voltage and current readings from a power meter operably connected to the circuit under test at the processor for each test sequence;
transmitting the voltage and current readings for each test sequence from the automated circuit tester to the computer for display;
saving the voltage and current readings for each test sequence to at least one test data storage device;
initiating a ground monitor test sequence for the circuit being tested by the processor under one of program control and operator request from the computer;
receiving voltage and current readings from a power meter operably connected to the circuit under test at the processor for the ground monitor test sequence;
transmitting the voltage and current readings for the ground monitor test sequence from the automated circuit tester to the computer for display;
saving the voltage and current readings for the ground monitor test sequence to at least one test data storage device;
initiating one or more ground fault test sequences for the circuit being tested by the processor under one of program control and operator request from the computer;
receiving voltage and current readings from a power meter operably connected to the circuit under test at the processor for each of the one or more ground fault test sequences;
transmitting the voltage and current readings for each of the one or more ground fault test sequences from the automated circuit tester to the computer for display; and,
saving the voltage and current readings for each of the one or more ground fault test sequences to at least one test data storage device.

17. The method of claim 16 wherein the power equipment is mining equipment circuitry.

18. The method of claim 17 wherein the mining equipment circuitry is low and medium voltage three phase AC circuitry.

19. The method of claim 16 wherein the at least one storage device is resident remotely from the test unit.

20. The method of claim 16 further comprising generating a report from the saved voltage and current readings remotely from the test unit.
